(19) United States
(12) Patent Application Publication
(10) Pub. No.: US 2017/0098723 A1
(43) Pub. Date: Apr. 6, 2017

(54) CONTROLLIING POTENTIAL-INDUCED DEGRADATON OF PHOTOVOLTAIC MODULES

(71) Applicant: ARIZONA BOARD OF REGENTS ON BEHALF OF ARIZONA STATE UNIVERSITY, Scottsdale, AZ (US)

(72) Inventors: JAEWON OH, Chandler, AZ (US); Sai Tatapudi, Mesa, AZ (US); Govindasamy Tamizhmani, Gilbert, AZ (US); Stuart Bowden, Tempe, AZ (US)

(21) Appl. No.: 15/315,086

(22) PCT Filed: Jun. 10, 2015
(86) PCT No.: PCT/US2015/035087

§ 371 Date: Nov. 30, 2016

Related U.S. Application Data
(60) Provisional application No. 62/010,735, filed on Jun. 11, 2014.
(60) Provisional application No. 62/108,301, filed on Jan. 27, 2015.

(51) Int. Cl. H01L 31/048; H01L 31/049; H02S 30/10

(52) U.S. Cl. CPC H01L 31/048; H02S 30/10; H01L 31/0481; H01L 31/049

(57) ABSTRACT

Method for controlling a potential-induced degradation (PID) of a PV module. Embodiment includes modifying surface conductivity of the glass-cover of the PV module at least in proximity to an edge of the supporting frame to interrupt an electrically conductive path formed, between the supporting frame and the PV cell through the glass-cover, by ambient conditions. In a related embodiment, the electrically-insulating material is disposed between the glass-cover and the PV cell and. optionally, is additionally embedded in an encapsulating material in which the PV cell is embedded. Related embodiment includes assembling a PV module with a layer of electrically-insulating material configured to prevent the formation of such conductive path.

### CROSS-REFERENCE TO RELATED APPLICATIONS

This application claims the benefit of U.S. Provisional Patent Application Ser. No. 62/010,735 filed on Jun. 11, 2014 and titled “NOVEL METHOD TO PREVENT POTENTIAL-INDUCED DEGRADATION (PID) OF PHOTOVOLTAIC MODULES DURING MANUFACTURING OR AFTER FIELD INSTALLATION” and U.S. Provisional Patent Application Ser. No. 62/108,301 filed on Jan. 27, 2015 and titled “APPLICATION OF FLEXIBLE GLASS TO PREVENT PID IN PV MODULES.”

### STATEMENT REGARDING FEDERALLY SPONSORED RESEARCH

This invention was made with government support under contract DE-AC36-08GO028308 awarded by the Department of Energy. The government has certain rights in the invention.

### BACKGROUND

The invention generally relates to the field of photovoltaic conversion of solar energy and, in particular, to improving the quality of such conversion and longevity of the photovoltaic (PV) modules by controlling electrical-potential-induced degradation in such modules.

Potential-Induced Degradation (PID) is one of reliability problems observed in the field operation of photovoltaic (PV) modules. In a typical PV module that has a frame (usually made of metal, providing rigidity and strength to the module, and grounded during the operation of the module), there may exist an operational difference of electric potentials between the module frame and PV cell(s). In a typical PV system, in which numerous PV modules may be and often are connected in series in order to increase the output voltage, such difference of potentials between the module frame and the PV cells of the modules located towards the end of the string or series (which cells typically operate at high voltages) is understandably increased.

Among the degradation mechanisms related to high voltage stress, PID is recognized as being one of the most serious. It was demonstrated to decrease output power of a PV module by more than 30% within a short period of time, particularly in a PV module that employs very common p-base solar cells. Although the exact mechanism of PID is not yet fully understood, it has been observed that high voltages, high operating temperatures as well as humid ambient conditions appear to facilitate the PID.

one possible explanation relates to sodium-on migration that originates in the glass covering a PV module and provides a shunting current path between the supporting frame and PV cell(s), thereby causing the reduction of the output power.

Various methods to prevent or minimize PID have been proposed and utilized at the cell, module or system level. For example, it is known that a modification of an antireflection coating (ARC) on the cell surface is one of the ways preventing PID at the cell level. At the system level, the PV modules affected by the PID during daytime could be recovered by applying opposite difference of potentials at night, although a complete recovery cannot be achieved using this method. At the module level, attempts were made to prevent the PID with the use of alternative module components, such as the encapsulant material or glass. For example, the use of an ionomer instead of more conventional EVA (Ethylene Vinyl Acetate) as an encapsulant material was shown to reduce the PID, which is attributed to the conductivity of ionomer being much lower than that of EVA. Selecting a module-cover glass that does not include sodium, or glass having high electrical conductivity also appears to address the PID. However, replacing the constituent materials of the PV module in practice could prove to be expensive and/or less durable and reliable over the long life of the PV module.

Notwithstanding the demonstration of some success of the above-mentioned approaches, the methodologies known in related art up to-date involve a high-cost production and/or reduced reliability of the resulting product. More important, however, remains the fact that the existing methods address the PID only at the manufacturing level. In other words, such methods cannot be applied to PID-susceptible modules that are already installed and operating in the field at least because the re-assembly and/or change of components of the PV module is required to implement any of the existing methods, which is simply not practical. Owning to the rapid growth of the PV industry over the past several years, the number of the PV modules already installed and now operating is innumerable, and practically all of these modules are likely to not meet the (typically 25-year) PV-module warranty requirements because of the continued susceptibility of such modules to the PID.

Understandably, then, there is a need for a new way of addressing the problem of PID in PV modules. Such new approach should be capable of alleviating the PID problem in the already-installed PID modules.

### SUMMARY

The present invention overcomes the aforementioned drawbacks by providing a way to control the PID in photovoltaic modules via disrupting a path of electrical conductivity formed between a PV cell of the module and a frame supporting the module. As will be described in more detail below, this is achieved by judiciously imposing an electrically-insulating material between the two. In this manner, not only the PID is prevented regardless of the type of solar cells utilized in a given PV module, but—in stark contradistinction to the methods employed to-date—such PID prevention is readily realized whether a PV module is still in production or already operating in the field, thereby eliminating the major concern of the ever-maturing solar industry.

Embodiments provide a method for controlling a potential-induced degradation (PID) in a photovoltaic module is provided. The method includes interrupting a closed electrical circuit formed between a frame supporting a photovoltaic (PV) module and a PV cell of the PV module by ambient conditions.

Embodiments additionally provide a photovoltaic (PV) module. The PV module includes a PV cell having a front side and a back side, the PV cell disposed between an encapsulating layer at the front side and a backsheet at the back side, and a glass cover in front of the encapsulating layer. The PV module also includes a module frame mechanically supporting the PV cell and the glass cover in a fixed position with respect to one another, and

an electrically-insulating material disposed between an edge of the module frame and the PV cell to interrupt a closed electrical circuit defined through a surface of the glass cover between the edge and the PV cell by water vapor condensation on said surface.

A related embodiment provides a method for manufacturing a photovoltaic (PV) module is provided. The method includes assembling a photovoltaic module that includes a PV cell having a front side and a back side, the PV cell disposed between an encapsulating layer at the front side and a backsheet at the back side. The PV module also includes a glass cover in front of the encapsulating layer, and a module frame mechanically supporting said PV cell and the glass cover in a fixed position with respect to one another. The PV module further includes an electrically-insulating material disposed between an edge of the module frame and the PV cell, wherein the electrically-insulating material is configured to interrupt a closed electrical circuit defined through a surface of the glass cover between the edge and the PV cell by water vapor condensation on said surface.

Furthermore, an embodiment of a method for modifying a photovoltaic module subject to potential-induced degradation (PID) is provided. The method includes providing a photovoltaic (PV) module that includes one or more PV cells, and an encapsulating layer enveloping the one or more PV cells. The PV module also includes a glass cover positioned on a surface of the encapsulating layer, and a supporting frame mechanically supporting the one or more PV cells and the glass cover in a fixed position with respect to one another. The method also includes modifying a surface conductivity of the glass cover at least in proximity to an edge of the supporting frame to interrupt an electrically conductive path between the supporting frame and glass layer generated by ambient conditions.

### BRIEF DESCRIPTION OF THE DRAWINGS

The following disclosure will be better understood in reference to the generally not-to-scale Drawings, of which:

FIG. 1 is a cross-sectional illustration of a PV module affected by ambient conditions.

FIG. 2 is a cross-sectional illustration of an embodiment configured in accordance with the idea of the present invention to control the PID in the PV module of FIG. 1.

FIG. 3A is a cross-sectional illustration of another embodiment of the PV module, related to that of FIG. 1 and configured to control the PID

FIG. 3A is a cross-sectional illustration of an alternative embodiment of a PV module configured to control the PID.

FIG. 4A is a cross-sectional illustration of an example of a PV module manufactured in accordance with an idea of the invention.

FIG. 4B is a cross-sectional illustration of another example of a PV module manufactured in accordance with an idea of the invention.

FIG. 5A presents a photograph of a PV coupon covered over its entire area with a Willow glass sheet, in accordance with an embodiment of the invention.

FIG. 5B a photograph showing edges of a PV coupon covered with a Willow glass sheet strips.

FIG. 6A is a side view schematic of a PV coupon partially covered with an electrically-insulating material (chosen, in this embodiment, to be a sheet of Willow glass).

FIG. 6B is a side view schematic of a PV coupon entirely covered with an electrically-insulating material (a sheet of Willow glass).

FIG. 6C is a side view schematic of a PV coupon covered with a Willow glass strips at the edges.

FIG. 6D provides a schematic of a related embodiment, in which a layer of an electrically-insulating material (shown as a sheet of Willow glass) is disposed between the glass cover and the PV cell and is, additionally, embedded within the encapsulating material.

FIG. 7A depicts electroluminescence images of a PV module covered Willow glass sheet, showing visible absence of PID damage.

FIG. 7B shows electroluminescence images of a reference sample without Willow glass cover, with clearly recognizable results of the PID damage.

FIG. 8A shows additional electroluminescence images of a PV module covered on the edges with a Willow glass sheet

FIG. 8B shows electroluminescence images of a reference sample without Willow glass cover, depicting PID damage.

FIG. 9A presents a plot of current-voltage characteristics of a PV module treated according to an embodiment of the invention.

FIG. 9B presents a plot of current-voltage characteristics of an untreated PV module.

FIG. 9C provides a comparison of performance parameters of untreated and treated PV modules.

### DETAILED DESCRIPTION

The present disclosure describes a novel approach substantially eliminate or at least minimize the PID issue both at the manufacturing stage of the PV module and after the operation of the PV module has committed. As described, the latter capability advantageously addresses a substantial need in solar industry, experiencing appreciable performance loss of the already-installed PV modules. In particular, the proposed methodology does not require modification of materials and/or replacement of components of the already-existing PV module structure, providing a low-cost, minimal-labor solution as compared to other methods existing in the industry.

A problem of loss of performance, caused by PID in a PV module, is solved by interrupting a path of electrical conductivity formed between a structural frame and a PV cell of the module.

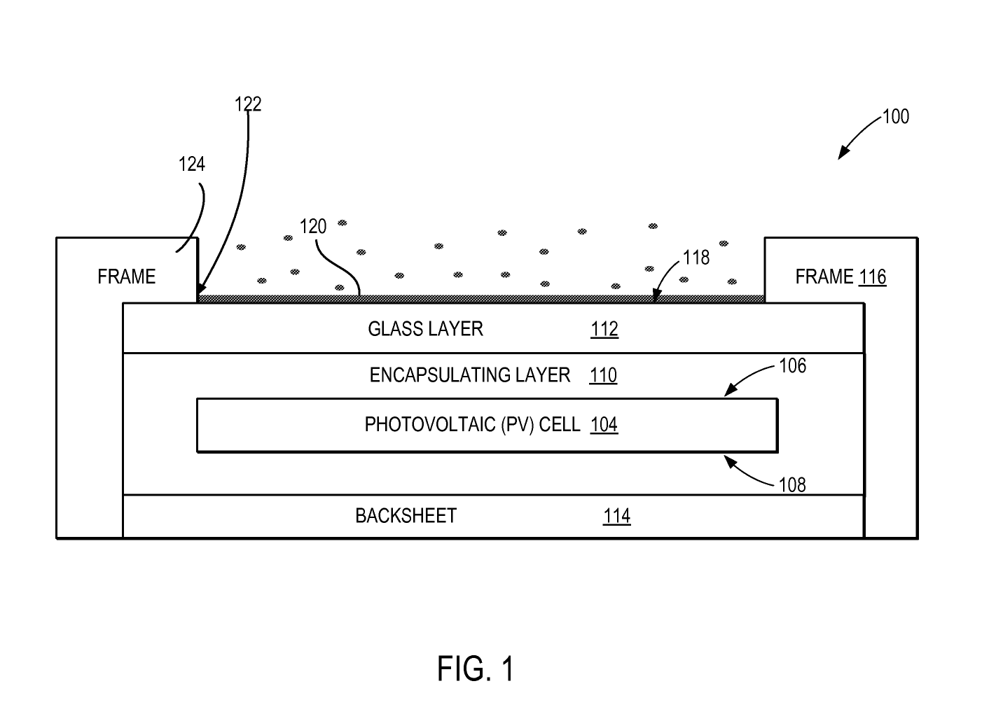

Referring specifically to FIG. 1, a cross-sectional schematic of a PV module 100 is shown. The PV module 100 includes a PV cell 104 that has a front side 106 and a back side 108 and that is encapsulated in an encapsulating material (layer) 110. The encapsulating layer 110 is shown to surround the cell 104, and is in contact with a glass layer 112 (referred to as glass cover) at the front of the module and a backsheet 114 at the back of the module. The PV module 100 also includes a supporting frame (module frame) 116, configured to mechanically support the overall structure and holding the PV cell 104 and the glass layer 112 in a fixed position with respect to one another.

It was empirically determined that electrical conductivity of the upper (facing the front of the module 100) surface 118 of the glass layer 112, formed and/or affected by ambient conditions, results in the PID of the module 100. In one instance, for example, such surface conductivity is caused by an electrically-conducting layer 120 of water-vapor condensation formed on the surface 118 and connecting the electrically-conducting frame 116 and the cover glass 112. When exposed to a large difference of electrical potentials difference (that can be as high as 1000 Volts, in some cases) between the frame 116 and the PV cell 104, the sodium ions in the glass layer 112 migrate towards the tacking faults of the cell. As such, a closed electrical circuit (an electrical path), is formed between the supporting frame 116 and the PV cell 104 through the conducting layer 120 present on the surface 118 of the glass layer 112. Such closed electrical circuit remains even when the “lip” 124 of the frame 116, disposed over the peripheral portion of the cover glass 112, is electrically insulated from the glass 112: in this case, the electrical path is typically defined in proximity to and by the edge 122 of the frame 116 and the surface 118.

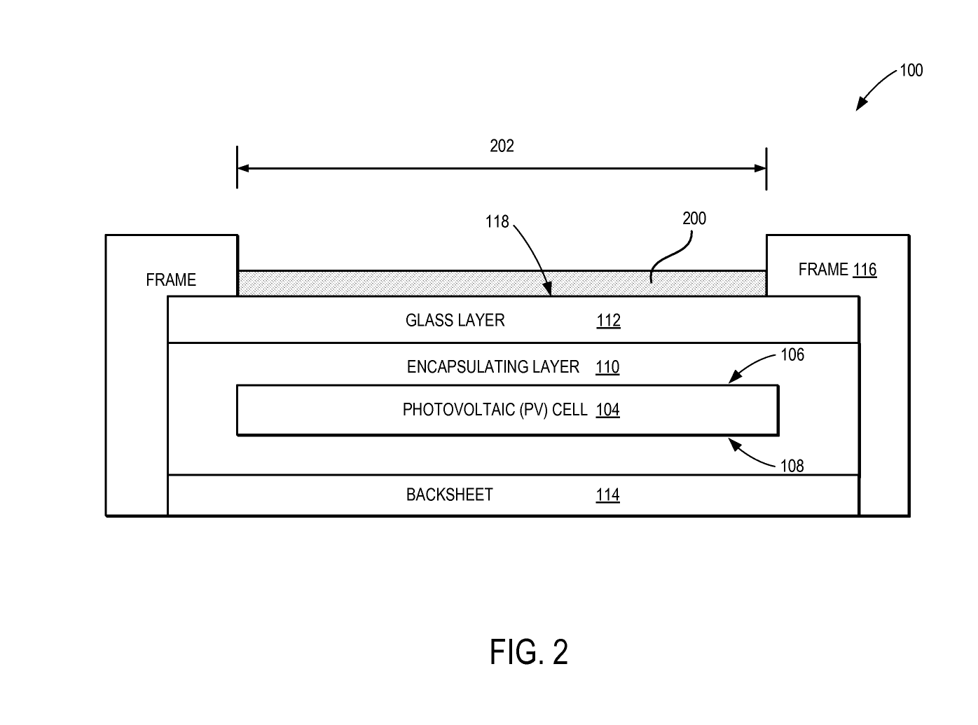

In one implementation of the idea of the invention, an electrically-insulating material is disposed on the surface 118 of the glass layer 112 to interrupt the closed electrical circuit so-formed through the PV module. Specifically referring now to FIG. 2, an electrically-insulating layer 200 is shown disposed on the surface 118 of the glass layer 112. The layer 200 preferably but not necessarily includes one or more materials or material compounds having electrically insulating properties, or highly resistive properties, in order to disrupt a surface conductivity of the glass layer 112. Alternatively or in addition, the electrically-insulating layer 200 can include hydrophobic or water-repelling material(s). In addition to being suitably dimensioned for interrupting the closed electrical circuit, as further described, it is desirable that the electrically-insulating layer 200 have properties that do not substantially affect the performance of the PV module 100. For example, the electrically insulating layer 200 can include a glass, such as Willow glass or Corning glass, having a thickness of about 100 micrometers, although other values may be possible. As shown in the embodiment of FIG. 2, the electrically-insulating layer 200 can extend over the entire length 202 or entire area of the clear aperture (open to collecting sunlight) of the PV module 100. It is appreciated, therefore, that the electrically-insulating layer 200 interrupts a closed electrical circuit produced by water vapor condensation between the frame 116 and the PV cell 104.

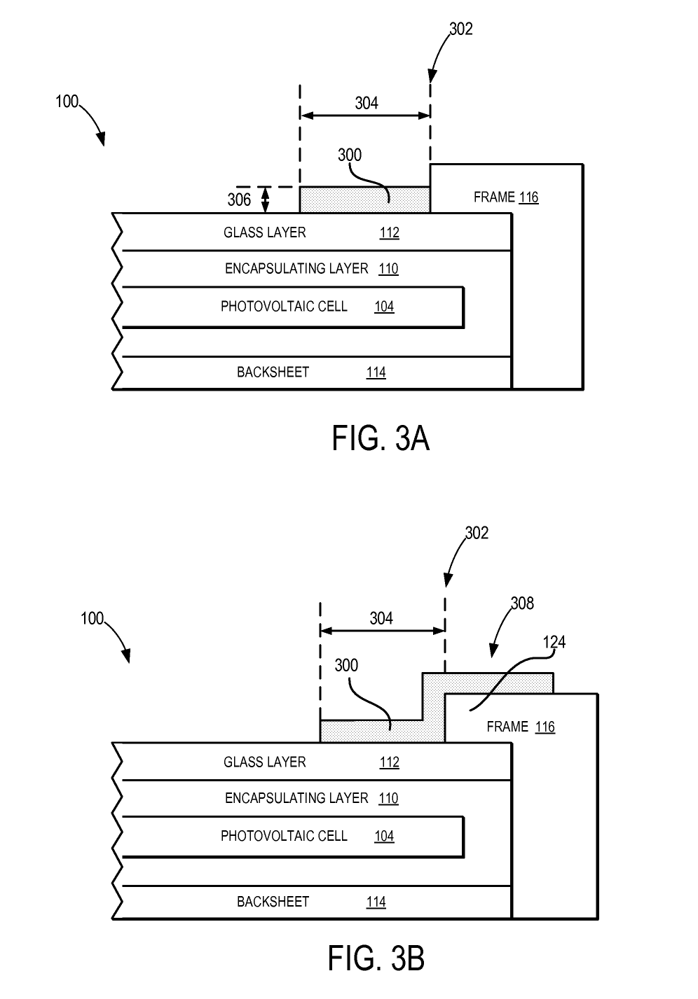

In another related embodiment, shown in FIG. 3A, an electrically-insulating layer 300 is disposed on the glass layer 112 in proximity to an edge surface 302 of the frame 116, the electrically-insulating layer 300 extending a distance 304 away from the surface 302. Similar to the insulating layer 200 of the embodiment of FIG. 2, the electrically-insulating layer 300 may include one or more materials or material compounds having electrically insulating properties in order to disrupt the surface conductivity of the glass layer 112. In addition, the electrically-insulating layer 300 can include a hydrophobic material, rubber, a polymeric material (in one implementation—glue), and an insulating tape (such as Kapton tape or electrically-insulating tape), for example.

The distance 304 at which the electrically-insulating layer 300 extends away from the edge surface 302 of the frame 116 is chosen to be in a range between a few millimeters (starting from about 1 mm) to a few centimeters (for example, between 1 and 5 cm), although other extents of the layer 300 may be chosen. A thickness 306 of a specific electrically-insulating layer 300 that possesses hydrophobic properties is configured to be sufficient to prevent unwanted electrical shorting as a result of the presence of ambient humidity. In particular, the electrically-insulating layer 300 may be configured to be substantially contiguous and non-porous such that the resistivity of the electrically-insulating layer 300 is as high as that of glass to prevent electrical shorting.

In a variation of the embodiment of FIG. 3A, a portion 308 of the electrically-insulating layer 300 is disposed on the glass layer 112 to extend on and over the lip 124 of the frame 116, as show in FIG. 3B. For example, the portion 308 may extend a distance of up to 2 cm over the lip 124.

As described, in accordance with the idea of the invention, control of a potential-induced degradation in a photovoltaic module is achieved by interrupting a closed electrical circuit formed between a frame supporting a PV module, and a PV cell of the PV module. The result of interrupting is effectuated by positioning an electrically-insulating material, as described with reference to FIGS. 2, 3A and 3B on a glass layer covering the PV module, to provide a convenient and an inexpensive way to prevent, reduce, or minimize PID in PV modules that are already in the field and operational. In addition, there is no need for replacing or changing inverters or type of groundings at the PV system level.

In a situation when the PV module is being fabricated, however, a related implementation of the idea of the invention achieves similar result. IN this case, modifying the surface conductivity of the cover of the PV module at least in proximity to an edge of the supporting frame serves to interrupt an electrically conductive path between the supporting frame and the PV cell generated by ambient conditions.

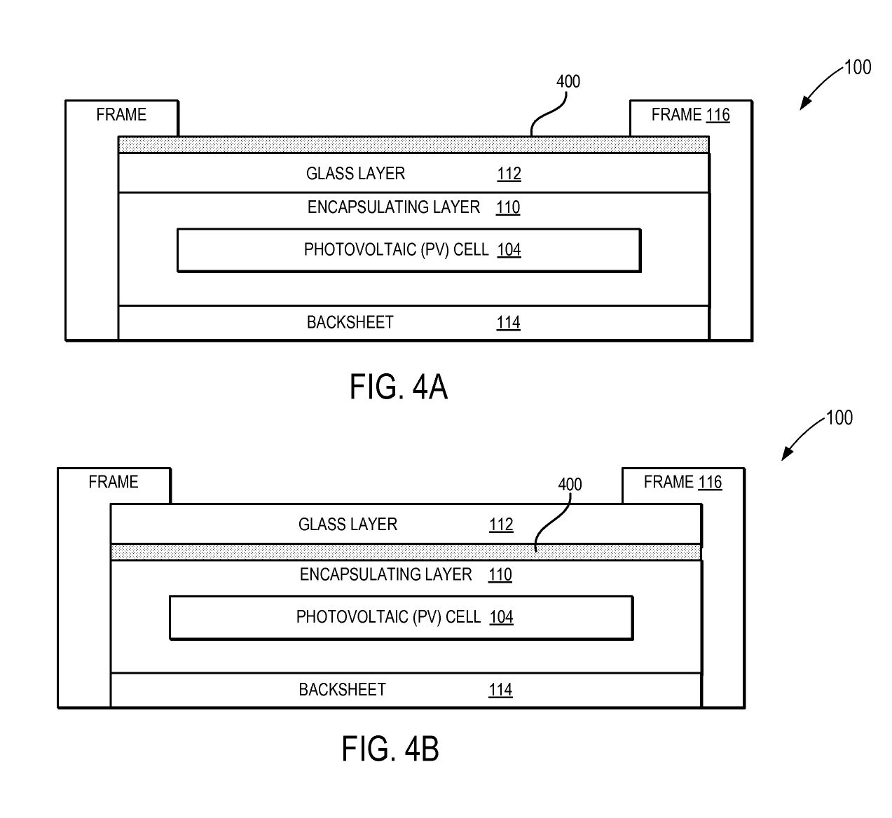

Such modification of the surface conductivity is implemented as the step of assembling the PV module. As is typically the case, a PV cell has a front side and a back side and is disposed between an encapsulating layer at the front side and a (supporting) backsheet at the back side. The encapsulating layer in some cases is used to encase the PV cell from all sides, thereby providing an envelope of a sort that is intended to prevent elements of the ambient environment from penetrating from the ambient medium towards the PV cell. The PV module also typically includes a glass cover in front of the encapsulating layer, and a module frame mechanically supporting said PV cell and the glass cover in a fixed position with respect to one another. At the step of assembly, an embodiment of the method of the invention includes a disposition of an electrically-insulating material between an edge of the module frame and the PV cell. In one implementation, the electrically-insulating material is disposed just under the lip of the frame and extends from the lip of the frame towards the center of the clear aperture of the PV cell while not covering the entire clear aperture of the PV cell. In a related embodiment, a layer of such material is positioned to cover the entire clear aperture of the PV cell while extending under the lip of the frame. In either case, so disposed, the electrically insulating material interrupts, in operation of the module, the closed electrical circuit defined through a surface of the glass cover between the edge and the PV cell by water vapor condensation on the surface, as discussed above. The most striking advantage of this approach in comparison with the related art is that no change in materials, components, assembly processes already present in presently developed and verified technologies is required. FIGS. 4A and 4B provide schematic illustrations of the specific embodiments of the PV module assembled such that the electrically-insulating layer 400 extends over an entire length or area of the PV module 100 and covers the clear aperture of the PV cell 104. Depending on the specifics of the assembly, the layer 400 can be positioned either on top of the cover glass layer 112 (FIG. 4A) or below the glass layer 112 (FIG. 4B).

In the present disclosure, the concept of disrupting surface conductivity or providing a high surface resistance for a glass layer covering a PV module was described in order to control PID. In particular, at least a portion of the glass surface can be modified using a water repellent or a material of high surface resistance, or an electrically-isolating or hydrophobic coating, or variations thereof, as described. In addition, such configurations can also be achieved during the manufacturing process. This approach can be further understood by way of the non-limiting example described below.

### Examples

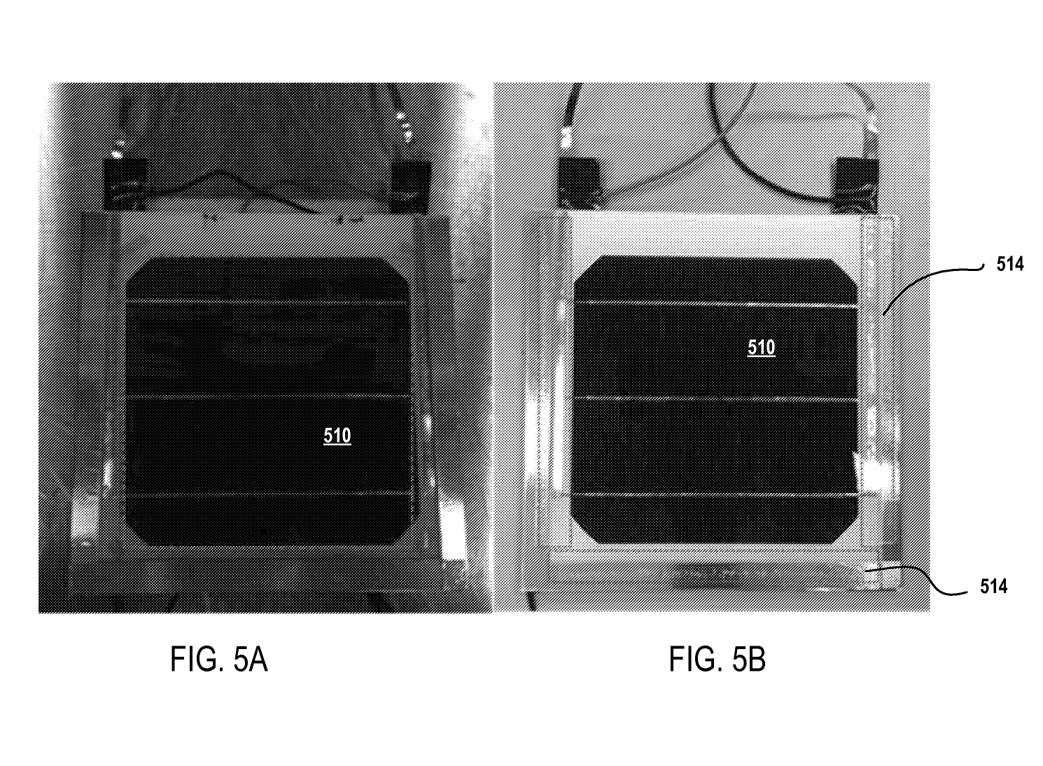

As shown in FIGS. 5A, 5B in top views, standard commercial 156×156 mm² p-base monocrystalline-Si solar cells 510 susceptible to PID were investigated. Each cell was laminated, using a commercial laminator, such that each one-cell coupon had a common PV module structure (glass-EVA-cell-EVA-backsheet). Typical commercial grade PV module materials, such as soda-lime solar glass (8×8 inch²), EVA, TPE backsheet, were chosen for fabricating these one-cell coupons. As a proxy for the aluminum supporting frame of the module, an aluminum tape 514 with conductive adhesive was attached on the three out of four edges of coupon. Aluminum tape was not attached on top edge (as shown) due to positive and negative leads as shown in FIGS. 5A and 5B.

In order to replicate and accelerate PID, three test conditions were addressed: temperature, humidity, and voltage. To simplify the test setup, the effect caused by high humidity on the PV module—specifically, high glass-surface conductivity—could be imitated by adding an electrically-conductive layer, such as an aluminum foil, on a surface of the cover glass, thereby simplifying the test by not requiring the humidity-controlled test chamber. Both methods were used in this experiment.

The PID stress was applied at Temperature/Relative-Humidity (or T degC/% RH) conditions imitating 60° C./0% and/or 60° C./85% RH with an applied voltage of about 600V on the cell with respect to aluminum tape at the edges. The 0% RH condition was approximated by the glass surface not covered with an aluminum tape, while the 85% RH condition was approximated when the surface of the glass cover was fully covered with aluminum tape and such aluminum tape was overlapped at the edges with the element representing the frame. Characterization of all one-cell coupons was carried out by determining light current-voltage (I-V) dependencies, dark I-V dependencies, and electroluminescence (EL) imaging before and after the PID stress tests.

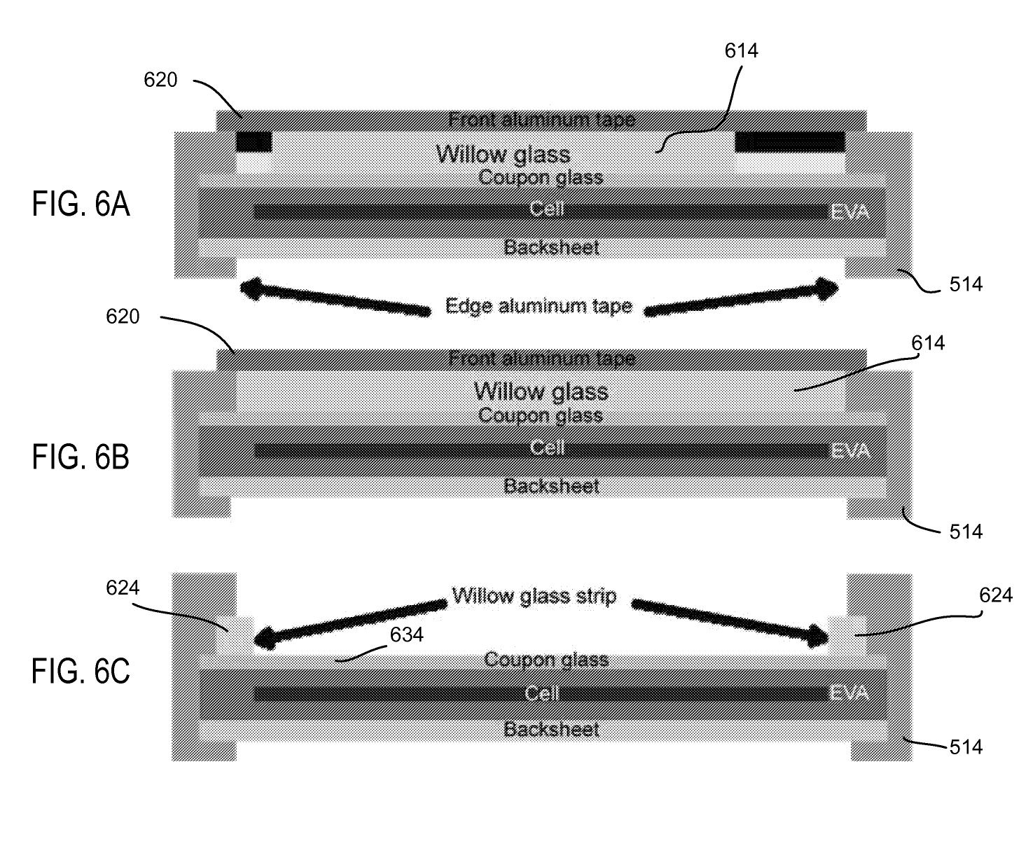

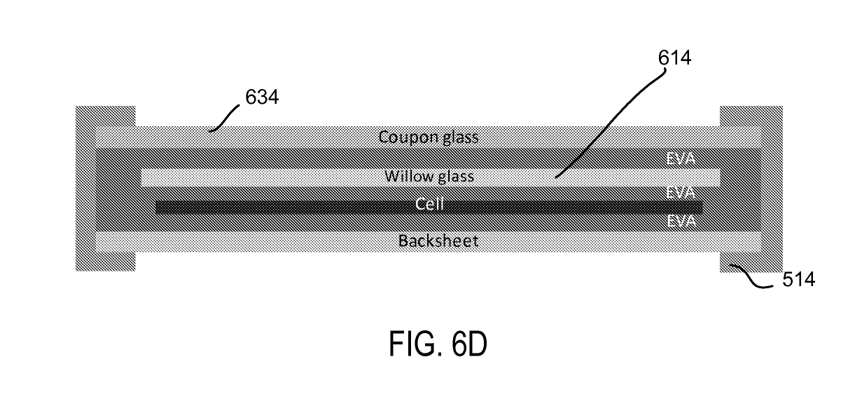

In further reference to FIGS. 6A, 6B, 6C and 6D, showing schematically embodiments of the PV modules configured according to the idea of the invention, the edge aluminum tape 514 is shown to emulate the conductive supporting frame of the module. For the electrically-insulating material, the so-called Willow Glass was used. (Relevant information about this material can be found at the Corning web-page.) It is very light, thin (about 100 micrometers) and flexible. Since it has a special composition including alkali-free borosilicate, such material was considered to be a good candidate for an electrically-insulating material 614, 624 in addressing the PID issue. The Willow Glass element 614, 624 used in this study was cut to size to fit the one-cell coupons. As shown in Table I, 3 different sizes of the Willow Glass samples were used, namely coupon A, coupon B, and coupon C, as well as a reference coupon.

TABLE 1
Test coupons used in the present study.

| | Willow Glass | | |
|---|---|---|---|
| | size | | Aluminum tape location |
| Coupon A | 10 × 10 | cm | Front aluminum tape |
| Coupon B | 16 × 16 | cm | Front aluminum tape |
| Coupon C | 2 × 17.5 | cm | Edge aluminum tape |

| | | |
|---|---|---|
| Reference | No glass | N/A |
| Coupon | | |

During the assembly of the embodiments of the invention, the Willow Glass material was fixed on the cover glass of the test coupons in two different ways. In one implementation, a square sheet 614 was placed on a one-cell coupon, and then aluminum tape was added to cover the whole surface corresponding to the clear aperture of the PV cell including sheet 614 (in coupons A and B), as shown in FIGS. 6A and 6B. The sheet of electrically-insulating material 614 used in coupon A was smaller in size than the PV cell, and the rest of the area was insulated by Kapton tape and electrical insulation tape. Since the front aluminum layer 620 covered the whole cell surface, no additional surface wetting or ambient humidity was required to carry out the PID test. In a related implementation of the assembly, the edge aluminum tape 514 (representing the frame) was used to fix rectangular Willow Glass strip 624 placed around edges (coupon C, FIG. 6C). Only half of the glass strip 624 was covered by the edge aluminum tape 514, as shown FIGS. 5B and 6C. Coupon C had no front surface aluminum tape 620, so such assembly was emulating the 85% RH conditions. The reference coupon PID setup followed each coupon's test conditions. Thus, 0%/RH was set for reference coupons of coupon A and B, and 85% RH for coupon C. In yet another related implementation of FIG. 6D, a layer of an electrically-insulating material (shown as a sheet of Willow glass) is disposed between the glass cover and the PV cell and is, additionally, embedded within the encapsulating material.

### A. An Embodiment with a Square Sheet of Electrically-Insulating Material for Surface Conductivity Interruption

The sheet 614 of coupon A was smaller than the PV cell, so Kapton tape was used on the rest of area between the edge of the aluminum elements 514 and the PV cell in order to prevent electrical contact. There was no dark region observed in the EL image, which clearly indicated that the PID-affected area was not present (and did not originated) where the electrically-insulating (Willow Glass) element was used to complement the PV module. The I-V curves additionally clearly showed that there was no degradation. Since this “humidity-approximating” concept worked, coupon B with the Willow Glass material covering the whole cell was assembled and stressed in a test chamber.

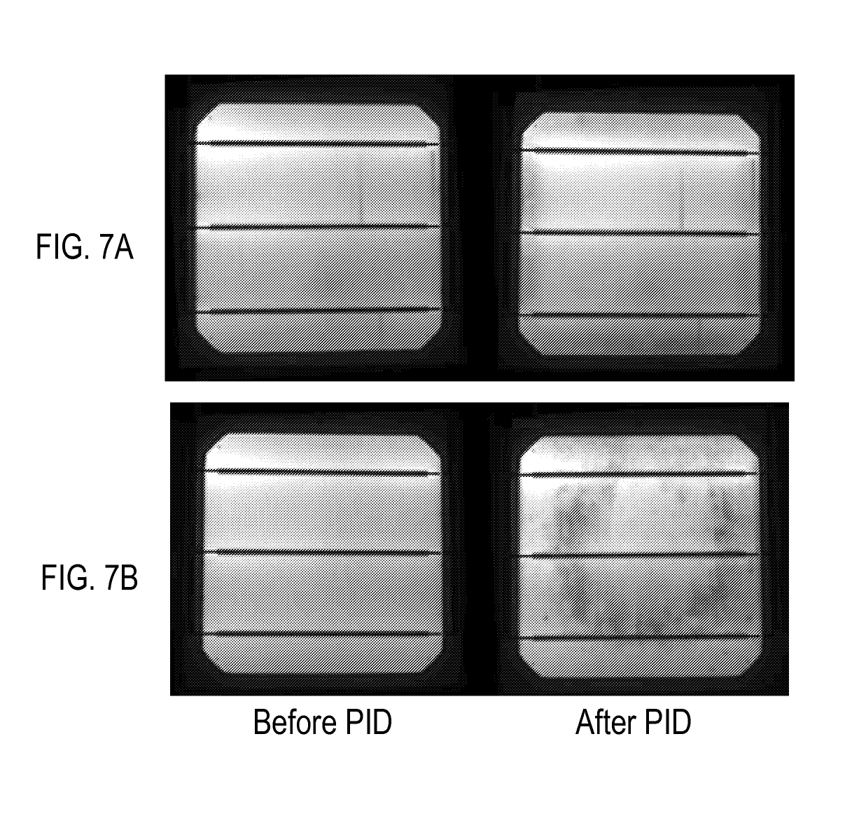

As shown in the electroluminescence images of FIG. 7A, coupon B also has no PID on the area where the Willow Glass material was placed, while reference coupon (shown in FIG. 7B) experienced PID all over the area of the clear aperture of the PV cell, as a person of skill in the art will readily recognize by discoloration of the module. Therefore, it is envisioned that an electrically-insulating material such as Willow Glass, for example, is a candidate for an insulating barrier to block sodium transport to the PV cells even in the presence of the soda-lime glass cover at the module.

### B. Rectangular Strip of Electrically-Insulating Material for Edge-Cell Circuit Interruption

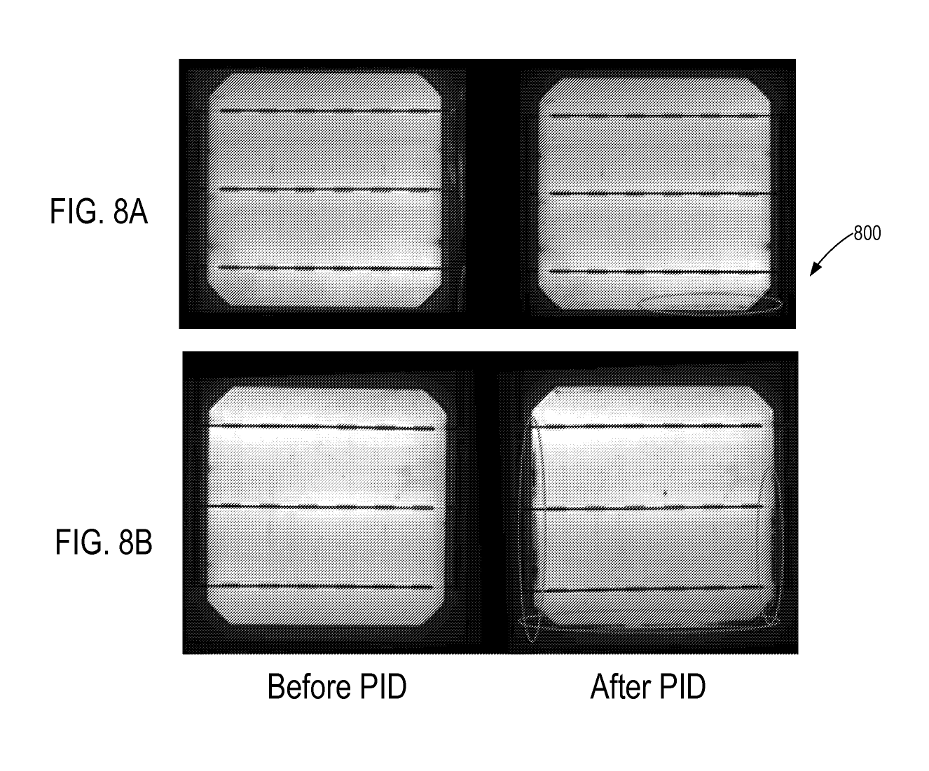

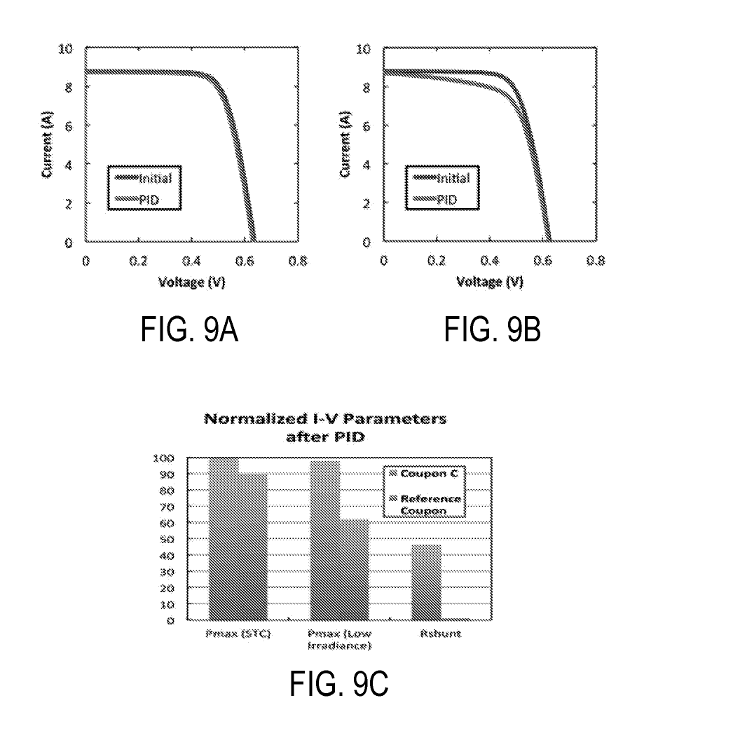

It was also shown that PID can be prevented/mitigated when the surface conductivity near edge/frame of PV module is interrupted. Half of the electrically-insulating material (such as the Willow Glass material) strip with no the adhesive tape was fixed by edge aluminum tape, so the Willow Glass contacts directly on the coupon sods-line cover glass 634, as shown in FIG. 6C. FIGS. 8A and 8B show electroluminescence images demonstrating that PID was prevented in coupon C due to surface disruption caused by Willow Glass strips 624, in comparison with the reference sample. As shown in the I-V plots of FIGS. 9A and 9C, Coupon C of FIG. 6C has nearly no degradation in terms of maximum power (Pmax), while the Pmax of reference coupon (FIG. 9B, FIG. 9C) experiences a power loss of 10% at STC and 40% at low irradiance. Notably, the edge portion shown as area 800 of cell in coupon C in FIG. 8A was somewhat affected by PID, which resulted in about 55% decrease of shunt resistance (Rsh) as shown in FIG. 9C. It was determined that this effect was caused by the conductive path formed by water ingress during the PID stress test itself. Such conductive path can be prevented by avoiding the water ingress using an improved test setup.

Therefore, it is readily understood by a person of ordinary skill in the art, that the present invention addresses a PV module that includes i) a PV cell having a front side and a back side, the PV cell disposed between an encapsulating layer at the front side and a backsheet at the back side; ii) a glass cover in front of the encapsulating layer, iii) a module frame configured to mechanically support the PV cell and the glass cover in a fixed position with respect to one another; and iv) an electrically-insulating material disposed between an edge of the module frame and the PV cell to interrupt a closed electrical circuit defined through a surface of the glass cover between the edge and the PV cell by water vapor condensation on said surface. The electrically-insulating material (the examples of which are glass, a hydrophobic material, a rubber, a polymeric material, and an insulating tape) in such module can be disposed on top of at least a portion of the surface of the glass cover. Alternatively or in addition, the electrically-insulating material can be disposed proximate to the edge of the frame on the surface. Alternatively or in addition, the electrically-insulating material can be disposed between the glass cover of the module and the PV cell and, optionally, embedded into an encapsulating material in which the PV cell is embedded.

A method for manufacturing of a PV module, provided by one implementation of the invention, includes (i) positioning a PV cell between a glass cover and a backsheet to form a layered structure; (ii) disposing an electrically-insulating material between an edge of the module frame and the PV; and (iii) affixing an electrically-conducting module frame around a perimeter of the layered structure. The step of disposing, in one implementation, includes disposing the electrically-insulating material between a lip of the frame and the glass cover; while in a related embodiment it includes disposing a layer of the electrically insulating material in contact with the glass cover to completely cover a clear aperture of the module with the electrically-insulating material. Alternatively or in addition, the step of disposing include positioning the electrically-insulating material over the glass cover such that the electrically-insulating material is exposed to an ambient medium (which surrounds the PV module).

References throughout this specification to “one embodiment,” “an embodiment,” “a related embodiment,” or similar language mean that a particular feature, structure, or characteristic described in connection with the referred to “embodiment” is included in at least one embodiment of the present invention. Thus, appearances of the phrases “in one embodiment,” “in an embodiment,” and similar language throughout this specification may, but do not necessarily, all refer to the same embodiment. It is to be understood that no portion of disclosure, taken on its own and in possible connection with a figure, is intended to provide a complete description of all features of the invention.

In addition, when the present disclosure describes features of the invention with reference to corresponding drawings (in which like numbers represent the same or similar elements, wherever possible), the depicted structural elements are generally not to scale, and certain components may be enlarged relative to the other components for purposes of emphasis and understanding. It is to be understood that no single drawing is intended to support a complete description of all features of the invention. In other words, a given drawing is generally descriptive of only some, and generally not all, features of the invention. A given drawing and an associated portion of the disclosure containing a description referencing such drawing do not, generally, contain all elements of a particular view or all features that can be presented is this view, at least for purposes of simplifying the given drawing and discussion, and directing the discussion to particular elements that are featured in this drawing. A skilled artisan will recognize that the invention may possibly be practiced without one or more of the specific features, elements, components, structures, details, or characteristics, or with the use of other methods, components, materials, and so forth. Therefore, although a particular detail of an embodiment of the invention may not be necessarily shown in each and every drawing describing such embodiment, the presence of this particular detail in the drawing may be implied unless the context of the description requires otherwise. In other instances, well known structures, details, materials, or operations may be not shown in a given drawing or described in detail to avoid obscuring aspects of an embodiment of the invention that are being discussed. Furthermore, the described single features, structures, or characteristics of the invention may be combined in any suitable manner in one or more further embodiments.

Moreover, if the schematic flow chart diagram is included, it is generally set forth as a logical flow-chart diagram. As such, the depicted order and labeled steps of the logical flow are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow-chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Without loss of generality, the order in which processing steps or particular methods occur may or may not strictly adhere to the order of the corresponding steps shown.

The invention as recited in claims appended to this disclosure is intended to be assessed in light of the disclosure as a whole, including features disclosed in prior art to which reference is made.

The present invention has been described in terms of one or more preferred embodiments, and it should be appreciated that many equivalents, alternatives, variations, and modifications, aside from those expressly stated, are possible and within the scope of the invention.

1. A method for manufacturing a photovoltaic (PV) module, the method comprising:
providing a PV module in which a PV cell is positioned between a glass cover and a backsheet to form a layered structure;
disposing an electrically-insulating material between an edge of the module frame and the PV; and
affixing an electrically-conducting module frame around a perimeter of the layered structure.

2. The method of claim 1, wherein the disposing includes disposing the electrically-insulating material between a lip of the frame and the glass cover, said electrically-insulating material including at least one of a glass material, a hydrophobic material, a rubber, a polymeric material, and an insulating tape.

3. The method of claim 1, wherein the disposing includes disposing a layer of the electrically insulating material in contact with the glass cover to completely cover a clear aperture of the module with the electrically-insulating material.

4. The method of claim 1, wherein said disposing includes positioning the electrically-insulating material over the glass cover such that the electrically-insulating material is exposed to an ambient medium surrounding the PC module.

5. The method of claim 1, wherein said disposing includes positioning the electrically-insulting material between the glass cover and the PV cell and embedding said electrically-insulating material in an encapsulating layer.

6. The method according to claim 1, wherein said providing includes assembling said PV cell between the glass cover and the backsheet of the PV module.

7. A photovoltaic (PV) module comprising:
a PV cell having a front side and a back side, the PV cell disposed between an encapsulating layer at the front side and a backsheet at the back side;
a glass cover in front of the encapsulating layer,
a module frame configured to mechanically support the PV cell and the glass cover in a fixed position with respect to one another; and
an electrically-insulating material disposed between an edge of the module frame and the PV cell to interrupt a closed electrical circuit defined through a surface of the glass cover between the edge and the PV cell by water vapor condensation on said surface.

8. The module of claim 7, wherein the electrically-insulating material is positioned on top of at least a portion of the surface of the glass cover.

9. The module of claim 7, wherein the electrically-insulating material is proximate to the edge of the frame on the surface.

10. The module of claim 7, wherein the electrically-insulating material is disposed between the glass cover and the PV cell and is embedded inside the encapsulating layer.

11. The module of claim 7 wherein the electrically-insulating material includes one or more of a glass, a hydrophobic material, a rubber, a polymeric material, and an insulating tape.

12. A method for modifying a photovoltaic (PV) module subjected to potential-induced degradation (PID), the method comprising:
a. providing a photovoltaic module comprising:
i. one or more PV cells;
ii. an encapsulating layer enveloping the one or more PV cells;
iii. a glass cover positioned on a surface of the encapsulating layer,
iv. an electrically-conducting frame mechanically supporting the one or more PV cells and the glass cover in a fixed position with respect to one another; and
b. modifying a surface conductivity of the glass cover at least in proximity to an edge of the frame to interrupt a closed electrically conductive path caused by an ambient medium between the supporting frame and glass layer, said ambient medium surrounding the PV module.

13. The method of claim 12, further comprising positioning an electrically-insulating material on top of at least a portion of a surface of the glass cover.

14. The method of claim 13, wherein said positioning includes disposing the electrically-insulating material in contact with said surface in contact with the edge.

15. The method of claim 13, wherein said positioning includes disposing the electrically-insulating material containing one or more of a glass, a hydrophobic material, a laminate, a rubber, a glue, or an insulating tape.

16. A method for controlling a potential-induced degradation (PID) in a photovoltaic (PV) module, the method comprising:
interrupting a closed electrical circuit caused by conditions of an ambient medium between a frame supporting the PV module and a PV cell of the PV module,
the ambient medium surrounding the PV module.

17. The method of claim 16, wherein the PV cell is disposed between an encapsulating layer at the front side and a backsheet at the back side.

18. The method of claim 17, wherein the PV cells further comprises a glass cover in front of the encapsulating layer.

19. The method of claim 16, wherein the closed electrical circuit is defined through a surface of the glass cover between an edge of the frame of the PV cell by a water vapor condensation on the surface.

20. The method of claim 19, further comprising disposing an electrically insulating material between the glass cover and the PV cell.

21. The method of claim 20, further comprising encapsulating the electrically-insulating material into at least one of an ionomer and Ethylene Vinyl Acetate.

22. The method of claim 19, further comprising positioning an electrically-insulating material on top of at least a portion of the surface.

23. The method of claim 22, wherein the electrically-insulating material is one of a glass, a hydrophobic material, a rubber, a polymeric material, and an insulating tape.

24. The method of claim 22, wherein the electrically-insulating material is proximate to an edge of the frame on the surface.

25. The method of claim 22, wherein the electrically-insulating material covers a portion of the frame.

26. The method of claim 24, wherein the electrically-insulating material wherein extends a distance away from the edge.
